(19) United States
(12) Patent Application Publication
(10) Pub. No.: US 2019/0057866 A1
(43) Pub. Date: Feb. 21, 2019

(54) CRYSTAL, CRYSTALLINE FILM, SEMICONDUCTOR DEVICE INCLUDING CRYSTALLINE FILM, AND METHOD FOR PRODUCING CRYSTALLINE FILM

(71) Applicants: FLOSFIA INC., Kyoto (JP); NATIONAL INSTITUTE FOR MATERIALS SCIENCE, Ibaraki (JP); KYOTO UNIVERSITY, Kyoto (JP); SAGA UNIVERSITY, Saga (JP)

(72) Inventors: Yuichi OSHIMA, Ibaraki (JP); Shizuo FUJITA, Kyoto (JP); Kentaro KANEKO, Kyoto (JP); Makoto KASU, Saga (JP); Katsuaki KAWARA, Kyoto (JP); Takashi SHINOHE, Kyoto (JP); Tokiyoshi MATSUDA, Kyoto (JP); Toshimi HITORA, Kyoto (JP)

(21) Appl. No.: 16/106,931

(22) Filed: Aug. 21, 2018

(30) Foreign Application Priority Data
Aug. 21, 2017 (JP) 2017-158308
Mar. 19, 2018 (JP) 2018-50517

(51) Int. Cl. H01L 21/02; H01L 29/24; C30B 25/04; C30B 25/18; C30B 29/20

(52) U.S. Cl. CPC H01L 21/02565; H01L 21/0242; H01L 21/0243; H01L 21/02483; H01L 21/02499; C30B 25/18; H01L 29/24; C30B 25/04; C30B 25/183; C30B 29/20; H01L 21/0262

(57) ABSTRACT

According to an aspect of a present inventive subject matter, a crystal includes: a corundum-structured oxide semiconductor as a major component, the corundum-structured oxide semiconductor including gallium and/or indium and doped with a dopant including germanium; a principal plane; a carrier concentration that is 1×10¹⁸/cm³ or more; and an electron mobility that is 20 cm²/Vs or more.

### CROSS-REFERENCE TO RELATED APPLICATION

This application is a new U.S. patent application that claims priority benefit of Japanese patent applications No. 2017-158308 filed on Aug. 21, 2017 and No. 2018-050517 filed on Mar. 19, 2018, the disclosures of which are incorporated herein by reference in its entirety.

### BACKGROUND OF THE INVENTION

### Field of the Invention

The present disclosure relates to a crystal. Also, the present disclosure relates to a crystalline film. Furthermore, the present disclosure relates to a semiconductor device including a crystalline film. Furthermore, the present disclosure relates to a method for producing a crystalline film.

### Description of the Related Art

As a background, gallium oxide (Ga₂O₃) is known to possess five different polymorphs including α-, β-, γ-, δ-, and ε-phases (for reference, see NPL1: Rustum Roy et al, “Polymorphism of Ga₂O₃ and the System Ga₂O₃—H₂O”).

Among these five polymorphs, β-Ga₂O₃ is believed to be thermodynamically the most stable, and α-Ga₂O₃ is believed to be metastable. Gallium oxide (Ga₂O₃) exhibits wide band gap and attracts more attention as a potential semiconductor material for semiconductor devices.

According to NPL 2, it is suggested that a band gap of gallium oxide (Ga₂O₃) is able to be controlled by forming mixed crystal with indium and/or aluminum (for reference, see NPL 2: Kentaro KANEKO, “Fabrication and physical properties of corundum-structured alloys based on gallium oxide”, Dissertation, Kyoto Univ., issued in March 2013, summary and contents were open to the public on Jan. 31, 2014). Among them, InAlGaO based semiconductors represented by In_{X}Al_{Y}Ga_{Z}O₃ (0≤X≤2, 0≤Y≤2, 0≤Z≤2, X+Y+Z=1.5 to 2.5) are extremely attractive materials (for reference, see PCT international publication No. WO2014/050793A1).

However, since β-phase is the most stable phase of gallium oxide, it is difficult to form a metastable corundum-structured crystalline film of gallium oxide without using a suitable film-formation method. Also, bulk substrates obtained from melt-growth are not available for α-Ga₂O₃ that is corundum-structured and metastable. Accordingly, sapphire substrates having a same structure as the corundum structure α-Ga₂O₃ has are used to form α-Ga₂O₃ on the sapphire substrates, however, lattice mismatch of sapphire and α-Ga₂O₃ is not small (Δa/a˜4.5%, Δc/c˜3.3%) and thus, α-Ga₂O₃ crystalline film hetero-epitaxially grown on a sapphire substrate tends to include a high density of dislocations. Furthermore, there are further challenges to accelerate film-formation speed, to enhance quality of a crystalline film of α-phase gallium oxide and/or a crystalline film of mixed crystal of α-phase gallium oxide, to suppress crystal defects including occurrence of cracks, abnormal growth, crystal twinning, and/or curves of crystalline film. Under such circumstances, researches of corundum-structured crystalline semiconductor films are ongoing.

It is open to the public that a crystalline film of oxide is produced by a mist chemical vapor deposition (CVD) method using bromide or iodide of gallium and/or indium (see Japanese patent publication No. 5397794). Also, it is open in public that a multilayer structure includes a corundum-structured semiconductor layer on a corundum-structured base substrate, and a corundum-structured insulating layer (see Japanese patent publications No. 5343224 and No. 5397795 and unexamined Japanese patent publication No. JP2014-72533). Furthermore, film-formation by a mist CVD method using ELO substrates and void formation is disclosed (see unexamined Japanese patent publications No. 2016-100592, No. 2016-98166, No. 2016-100593, and No. 2016-155714). Also, it is open to the public that a corundum-structured gallium oxide film is formed by a halide vapor phase epitaxy (HVPE) method. However, there is a room for improvement in the rate or speed for forming a film, and a method for producing a crystalline film with a sufficient speed has been desired.

Also, considering that α-Ga₂O₃ is metastable, α-Ga₂O₃ films and crystalline films of crystalline metal oxide containing gallium and one or more metals are more difficult to form with suppressed defect density, compared to the case of stable β-Ga₂O₃, and thus, there are still various challenges to cope with for obtaining α-Ga₂O₃ films and crystalline films of crystalline metal oxide containing gallium and one or more metals.

### SUMMARY OF THE INVENTION

According to a first aspect of a present inventive subject matter, a crystal includes a corundum-structured oxide semiconductor as a major component, the corundum-structured oxide semiconductor including gallium and/or indium and doped with a dopant including germanium. The crystal includes a principal plane, a carrier concentration that is 1×10¹⁸/cm³ or more, and an electron mobility that is 20 cm²/Vs or more.

According to an embodiment of a crystal of a present inventive subject matter, it is suggested that the principal plane of the crystal is a c-plane.

Also, according to an embodiment of a crystal of a present inventive subject matter, the principal plane may be an m-plane.

Furthermore, it is suggested that the principal plane may include an off-angle.

According to an embodiment of a crystal of a present inventive subject matter, the corundum-structured oxide includes a mixed crystal containing gallium and one or more metals selected from among aluminum, indium, iron, chromium, vanadium, titanium, rhodium, nickel, cobalt, and iridium.

According to an embodiment of a crystal of a present inventive subject matter, the crystal has a film shape as a crystalline film.

According to an embodiment of a crystal of a present inventive subject matter, it may be suggested that the mixed crystal comprised in the corundum-structured oxide semiconductor contains aluminum that is 1×10¹⁷/cm³ or more.

According to a second aspect of a present inventive subject matter, a crystalline film includes an oxide semiconductor as a major component, the oxide semiconductor contains aluminum that is 1×10¹⁷/cm³ or more, includes a carrier concentration that is 1×10¹⁸/cm³ or more, and an electron mobility that is 20 cm²/Vs or more.

It is suggested that the oxide semiconductor contains gallium.

According to an embodiment of a present inventive subject matter, a crystalline film may include a metal oxide containing a mixed crystal.

According to a third aspect of a present inventive subject matter, a semiconductor device includes a crystal including a corundum-structured oxide semiconductor as a major component, the corundum-structured oxide semiconductor including gallium and/or indium and doped with a dopant including germanium. The crystal included in the semiconductor device includes a principal plane, a carrier concentration that is 1×10′⁸/cm³ or more, and an electron mobility that is 20 cm²/Vs or more. The semiconductor device further includes a first electrode electrically connected to the crystal, and a second electrode electrically connected to the crystal.

According to a fourth aspect of a present inventive subject matter, a semiconductor device includes a crystalline film containing an oxide semiconductor as a major component, the oxide semiconductor of the crystalline film containing aluminum that is 1×10¹⁷/cm³ or more; a carrier concentration that is 1×10¹⁸/cm³ or more; and an electron mobility that is 20 cm²/Vs or more. The semiconductor device further includes a first electrode electrically connected to the crystalline film; and a second electrode electrically connected to the crystalline film.

According to a fifth aspect of a present inventive subject matter, a method for producing a crystalline film includes: gasifying a metal source to turn the metal source into a metal-containing raw-material gas; supplying the metal-containing raw-material gas, an oxygen-containing raw-material gas into a reaction chamber onto a substrate; supplying a dopant-containing raw-material gas and a reactive gas into the reaction chamber onto the substrate; and forming a crystalline film under gas flow of the dopant-containing raw-material gas and the reactive gas.

It is suggested that the dopant-containing raw-material gas contains germanium.

Furthermore, it is suggested that the dopant-containing raw-material gas may be germanium halide gas.

According to an embodiment of a method for producing a crystalline film, the reactive gas may be an etching gas.

It is suggested that the reactive gas contains at least one selected from among hydrogen halide and groups comprising halogen and hydrogen.

According to an embodiment of a method for producing a crystalline film, it is suggested that a reactive gas contains hydrogen halide.

Also, it is suggested that a substrate has a corundum structure.

Furthermore, it is suggested that a crystalline film has a corundum structure.

According to an embodiment of a method for producing a crystalline film, it is suggested that a substrate may be heated with a temperature that is in a range of 400° C. to 700° C.

According to an embodiment of a method for producing a crystalline film, it is suggested that a metal source contains gallium, and the metal-containing raw-material gas contains gallium.

According to an embodiment of a method for producing a crystalline film, it is suggested that the gasifying the metal source is done by halogenating the metal source.

It is suggested that the oxygen-containing raw-material gas contains at least one selected from among oxygen (O₂), water (H₂O) and nitrous oxide (N₂O).

### BRIEF DESCRIPTION OF THE DRAWING

FIG. 1 shows a schematic perspective view showing a halide vapor phase epitaxy (HVPE) apparatus that is used in embodiments of a method for producing a crystalline film according to a present inventive subject matter.

FIG. 2 shows a schematic perspective view of a substrate with an uneven portion formed on a surface of the substrate according to an embodiment of a present inventive subject matter as an example.

FIG. 3 shows a schematic top plan view of a substrate with an uneven portion formed on a surface of the substrate according to a present inventive subject matter as an example.

FIG. 4 shows a schematic perspective view of a substrate with an uneven portion formed on a surface of the substrate according to a present inventive subject matter as an example.

FIG. 5 shows a top plan view of a substrate with an uneven portion formed on a surface of the substrate according to a present inventive subject matter as an example.

FIG. 6A shows a schematic perspective view of a substrate with an uneven portion formed on a surface of the substrate according to a present inventive subject matter as an example.

FIG. 6B shows a schematic top plan view of the substrate shown in FIG. 6A.

FIG. 7A shows a schematic perspective view of a substrate with an uneven portion formed on a surface of the substrate according to a present inventive subject matter as an example.

FIG. 7B shows a schematic top plan view of a substrate with an uneven portion formed on a surface of the substrate according to a present inventive subject matter as an example.

FIG. 8 shows schematic view of a semiconductor system according to an embodiment of a present inventive subject matter.

FIG. 9 shows a schematic view of a semiconductor system according to an embodiment of a present inventive subject matter.

FIG. 10 shows a schematic view of a circuit diagram of power supply of a semiconductor system according to an embodiment of a present inventive subject matter.

FIG. 11 shows a schematic view of a mist chemical vapor deposition (CVD) apparatus that is used in embodiments of a method for producing a crystalline film according to a present inventive subject matter.

FIG. 12 shows picture of a crystalline film formed on a substrate, according to an embodiment of a present inventive subject matter.

FIG. 13 shows a SIMS measurement result of a crystalline film obtained according to an embodiment of a present inventive subject matter.

FIG. 14 shows an XRD measurement result of a crystalline film obtained according to an embodiment of a present inventive subject matter.

FIG. 15 shows a graph, indicating a relationship of germanium (Ge) concentration in a crystalline film obtained according to an embodiment of a present inventive subject matter and supply quantity of GeCl₄. The vertical axis indicates Ge concentration 10¹⁹/cm⁻³ and the horizontal axis indicates supply quantity of GeCl₄ (sccm).

FIG. 16 shows a SIMS measurement result of a crystalline film obtained according to the Trial Embodiment 1 of a present inventive subject matter. The crystalline film obtained in the Trial Embodiment 1 was an α-Ga₂O₃ crystalline film that was grown without any dopant being doped first, then grown with germanium (Ge) being doped.

FIG. 17A shows an XRD measurement result of a crystalline film in 0006 diffraction and obtained without any dopant being doped, according to the Trial Embodiment 2.

FIG. 17B shows an XRD measurement result of a crystalline film in 0006 diffraction and obtained without Ge being highly doped, according to the Trial Embodiment 2.

FIG. 18 respectively shows a relationship of an electron mobility and a carrier concentration of a Ge-doped α-Ga₂O₃ crystalline film formed by an HVPE apparatus and a relationship of an electron mobility and a carrier concentration of an Sn-doped α-Ga₂O₃ crystalline film formed by a mist CVD apparatus.

FIG. 19 shows a schematic figure of an HVPE apparatus used in an embodiment of the Test Embodiment 1.

### DETAILED DESCRIPTION OF EMBODIMENTS

The terminology used herein is for the purpose of describing particular embodiments only and is not intended to be limiting of the subject matter. As used herein, the singular forms “a”, “an” and “the” are intended to include the plural forms as well, unless the context clearly indicates otherwise.

As used herein, the term “and/or” includes any and all combinations of one or more of the associated listed items.

As illustrated in the figures submitted herewith, some sizes of structures or portions may be exaggerated relative to other structures or portions for illustrative purposes. Relative terms such as “below” or “above” or “upper” or “lower” may be used herein to describe a relationship of one element, layer or region to another element, layer or region as illustrated in the figures. It will be understood that these terms are intended to encompass different orientations of a layer, a device, and/or a system in addition to the orientation depicted in the figures.

According to a first aspect of a present inventive subject matter, a crystal includes a corundum-structured oxide semiconductor as a major component, the corundum-structured oxide semiconductor including gallium and/or indium and doped with a dopant including germanium; a principal plane; a carrier concentration that is 1×10¹⁸/cm³ or more; and an electron mobility that is 20 cm²/Vs or more.

According to an embodiment, the mixed crystal contained in the corundum-structured oxide semiconductor contains aluminum that is 1×10¹⁷/cm³ or more.

Also, according to a second aspect of a present inventive subject matter, a crystalline film includes an oxide semiconductor as a major component, the oxide semiconductor contains aluminum that is 1×10¹⁷/cm³ or more; a carrier concentration that is 1×10¹⁸/cm³ or more; and an electron mobility that is 20 cm²/Vs or more.

According to an embodiment of the mixed crystal contained in the corundum-structured oxide semiconductor contains aluminum that is 1×10¹⁷/cm³ or more.

Furthermore, according to an aspect of a present inventive subject matter, a method for producing a crystalline film includes: gasifying a metal source to turn the metal source into a metal-containing raw-material gas; supplying the metal-containing raw-material gas, an oxygen-containing raw-material gas into a reaction chamber onto a substrate; supplying a dopant-containing raw-material gas and a reactive gas into the reaction chamber onto the substrate; and forming a crystalline film under gas flow of the dopant-containing raw-material gas and the reactive gas.

(Metal Source)

The metal source is not particularly limited as long as the metal source contains at least one metal and is able to be gasified. The metal source may be a metal source of an elemental metal. Also, the metal source may be a metal source of metal compound. Examples of metal contained in the metal source include gallium, aluminum, indium, iron, chromium, vanadium, titanium, rhodium, nickel, cobalt, and iridium. One or more metals may be contained in the metal source.

In an embodiment of a method for producing a crystalline film of a present inventive subject matter, the metal of the metal source may be at least one selected from among gallium, aluminum, and indium, but further preferably the metal of the metal source contains gallium. In an embodiment of a method for producing a crystalline film of a present inventive subject matter, the metal source is most preferably a gallium source.

Also, the metal source may be a gaseous source, a liquid source, and a solid source, however, if the metal of the metal source is gallium, a liquid source of gallium is preferable.

Gasifying a metal source to turn the metal source into a metal-containing raw-material gas is not particularly limited as long as an object of a present inventive subject matter is not interfered with and may be done by a known method. In embodiments of a present inventive subject matter, gasifying a metal source to turn the metal source into a metal-containing raw-material gas is preferably done by halogenating the metal source. A halogenating agent used for halogenating the metal source is not particularly limited as long as the metal source is able to be halogenated and may be a known halogenating agent. The halogenating agent may be halogen and/or hydrogen halide. Examples of halogen include fluorine, chlorine, bromine, and iodine. Also, examples of hydrogen halide include hydrogen fluoride, hydrogen chloride, hydrogen bromide, and hydrogen iodide. In embodiments of a present inventive subject matter, halogenating the metal source by use of hydrogen halide is preferable, and halogenating the metal source by use of hydrogen chloride is further preferable. In an embodiment of a method for producing a crystalline film, halogenating the metal source is preferably done by supplying halogen or hydrogen halide as a halogenating agent to the metal source and causing a reaction of the metal source and the halogenating agent at a vaporization temperature of a metal halide or higher temperatures of the vaporization temperature of the metal halide. The vaporization temperature is not particularly limited, however, in an embodiment that the metal of the metal source is gallium and the halogenating agent is hydrogen chloride, the vaporization temperature is preferably 900° C. or less, and further preferably 700° C. or less. The vaporization temperature is most preferably in a range of 400° C. to 700° C.

The metal-containing raw-material gas is not particularly limited as long as the metal-containing raw-material gas is a gas containing the metal of the metal source. Examples of the metal-containing raw-material gas may be a halogenating agent such as fluoride, chloride, bromide and iodide.

In embodiments of a present inventive subject matter, after gasifying a metal source to turn the metal source into a metal-containing raw-material gas, the meal-containing raw-material gas and an oxygen-containing raw-material gas are supplied into a reaction chamber onto a substrate. Also, in embodiments of a present inventive matter, a reactive gas is supplied into the reaction chamber onto the substrate. Examples of the oxygen-containing raw-material gas include oxygen (O₂) gas, carbon dioxide (CO₂) gas, nitric oxide (NO) gas, nitrogen dioxide (NO₂) gas, nitrous oxide (N₂O) gas, H₂O gas and ozone (O₃) gas. In embodiments of a present inventive subject matter, the oxygen-containing raw-material gas is preferably at least one selected from among O₂ gas, H₂O gas, and (N₂O) gas, and the oxygen-containing raw-material gas further preferably contains O₂ gas. According to an embodiment of a method for producing a crystalline film, the oxygen-containing raw-material gas may contain CO₂ gas. The reactive gas, usually different from the metal-containing raw-material gas and the oxygen-containing raw-material gas, excludes inert gas. The reactive gas is not particularly limited as long as an object of a present inventive subject matter is not interfered with, however, an etching gas is named as an example. The etching gas is not particularly limited as long as an object of a present inventive subject matter is not interfered with and may be a known etching gas. In embodiments of a method for producing a crystalline film, the reactive gas is preferably a halogen gas, a hydrogen halide gas, and/or a hydrogen gas. Examples of the halogen gas include a fluorine gas, a chlorine gas, bromine gas, and iodine gas. Examples of the hydrogen halide gas include a hydrofluoric acid gas, a hydrochloric acid gas, a hydrogen bromide gas, and a hydrogen iodide gas.

The reactive gas may be a mixed gas containing two or more gasses mentioned above, and the reactive gas preferably contains a hydrogen halide gas and most preferably contains hydrogen chloride.

Also, the metal-containing raw-material gas, the oxygen-containing raw-material gas, and the reactive gas may contain a carrier gas, respectively. The carrier gas may be an inert gas, as an example. Examples of the inert gas include nitrogen and argon.

Furthermore, a partial pressure of the metal-containing raw-material gas is not particularly limited but in embodiments of a method of a present inventive subject matter, the partial pressure of the metal-containing raw-material gas is preferably in a range of 0.5 Pa to 1 kPa, and further preferably in a range of 5 Pa to 0.5 kPa. Also, a partial pressure of the oxygen-containing raw-material gas is not particularly limited but in embodiments of a method of a present inventive subject matter, the partial pressure of the oxygen-containing raw-material gas is preferably in a range of 0.5 times to 100 times of the partial pressure of the metal-containing raw-material gas, and further preferably in a range of 1 to 20 times of the partial pressure of the metal-containing raw-material gas. In addition, a partial pressure of the reactive gas is not particularly limited but in embodiments of a method of a present inventive subject matter, the partial pressure of the reactive gas is preferably in a range of 0.1 times to 5 times of the partial pressure of the metal-containing raw-material gas, and further preferably in a range of 0.2 times to 3 times.

In embodiments of a method of a present inventive subject matter, a dopant-containing raw-material gas is further preferably supplied into the reaction chamber onto the substrate. The dopant-containing raw-material gas is not particularly limited as long as the dopant-containing raw-material gas contains a dopant. The dopant is also not particularly limited but in embodiments of a method of a present inventive subject matter, the dopant may contain one or more elements selected from among germanium, silicon, titanium, zirconium, vanadium, niobium, and tin. According to an embodiment of a present inventive subject matter, the dopant preferably contains germanium, silicon and/or tin, and most preferably contains germanium. By using the dopant-containing raw-material gas in the method for producing a crystalline film, it is possible to easily control electrical conductivity of the crystalline film to be obtained. The dopant-containing raw-material gas preferably contains a dopant in the form of compound. Examples of the dopant in the form of compound include a halide and an oxide. The dopant-containing raw-material gas further preferably contains a halide as a dopant. A partial pressure of the dopant-containing raw-material gas is not particularly limited but in embodiments of a method of a present inventive subject matter, the partial pressure of the dopant-containing raw-material gas is preferably in a range of 1×10⁻⁷ times to 0.1 times, and further preferably in a range of 2.5×10⁻⁶ times to 7.5×10⁻² times. Furthermore, in embodiments of a method of a present inventive subject matter, the dopant-containing raw-material gas is preferably supplied with the reactive gas into the reaction chamber onto the substrate.

(Substrate)

The substrate is not particularly limited as long as the substrate includes an uneven portion on a surface of the substrate and is able to support a crystalline film to be grown on the substrate. The uneven portion on the surface of the substrate may include at least one mask and at least one opening. The substrate may be a known substrate. The substrate may be an electrically-insulating substrate. The substrate may be an electrically-conductive substrate. Also, the substrate may be a semiconductor substrate. In embodiments of a method for producing a crystalline film of a present inventive subject matter, the substrate is preferably a crystalline substrate.

(Crystalline Substrate)

The crystalline substrate is not particularly limited as long as the substrate contains a crystal as a major component and may be a known substrate. The crystalline substrate may be an electrically-insulating substrate. Also, the crystalline substrate may be a semiconductor substrate. The crystalline substrate may be a monocrystalline substrate. Also, the crystalline substrate may be a polycrystalline substrate. Examples of the crystalline substrate include a substrate containing a corundum-structured crystal as a major component, a substrate containing a β-gallia-structured crystal as a major component, and a hexagonal-structured substrate. The term “major component” herein means that a composition ratio of the crystal in the crystalline substrate is 50% or more, preferably 70% or more, and further preferably 90% or more.

Examples of the substrate containing a corundum-structured crystal as a major component include a sapphire (α-Al₂O₃) substrate and an α-phase gallium oxide (α-Ga₂O₃) substrate. Examples of the substrate containing a β-gallia-structured crystal as a major component include β-phase gallium oxide (β-Ga₂O₃) substrate and a substrate containing a mixed crystal of β-Ga₂O₃ and α-Al₂O₃. As a substrate containing the mixed crystal of β-Ga₂O₃ and α-Al₂O₃, the substrate of the mixed crystal in which Al₂O₃ is contained in a range of more than 0% to 60% or less in terms of atomic ratio. Also, examples of the hexagonal-structured substrate include a silicon carbide (SiC) substrate, a zinc oxide (ZnO) substrate, a gallium nitride (GaN) substrate. An example of another crystalline substrate is a silicon (Si) substrate, for example.

In embodiments of a present inventive subject matter, the crystalline substrate is preferably a sapphire substrate. Examples of the sapphire substrate include a c-plane sapphire substrate, an m-plane sapphire substrate and an a-plane sapphire substrate. The sapphire substrate may include an off-angle. In an embodiment of a method for producing a crystalline film of a present inventive subject matter, the crystalline substrate is preferably a c-plane sapphire substrate. Also, in an embodiment of a method for producing a crystalline film of a present inventive subject matter, the crystalline substrate is preferably an m-plane sapphire substrate. If an m-plane sapphire substrate is used, setting the flow rate of the oxygen-containing raw-material gas to an increased quantity. For example, the flow rate of the oxygen-containing raw-material gas is set to 50 sccm (standard cubic centimeters per minute) or more. The flow rate of the oxygen-containing raw-material gas is preferably set to 70 sccm or more, according to an embodiment of a method for producing a crystalline film. According to an embodiment of a method for producing a crystalline film, the flow rate of the oxygen-containing raw material gas is most preferably 100 sccm or more. The off-angle of the sapphire substrate is not particularly limited, however, preferably in a range of 0° to 15°. Also, the thickness of the crystalline substrate is not particularly limited, however preferably in a range of 50 μm to 2000 μm, and further preferably in a range of 200 μm to 800 μm.

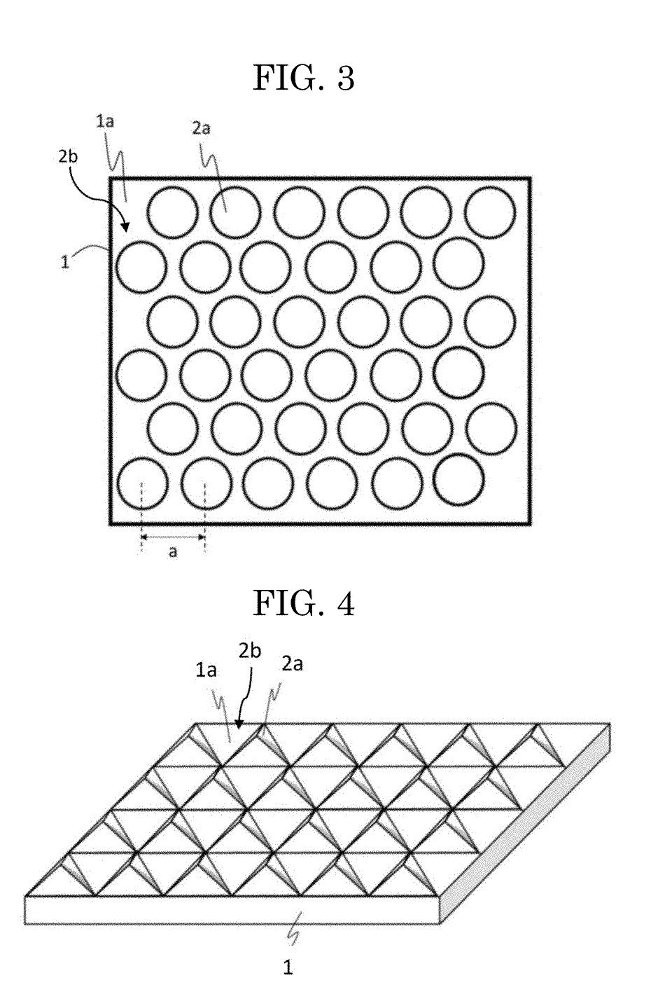

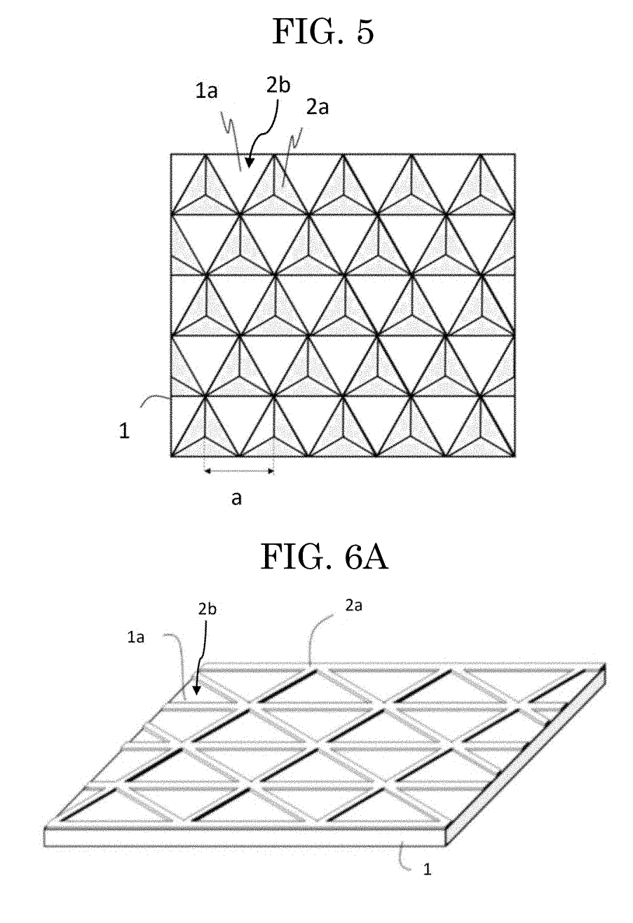

In embodiments of a present inventive subject matter, since the substrate includes an uneven portion that includes at least one mask and/or two or more openings, it is possible to produce a crystalline film efficiently. The uneven portion of the substrate is not particularly limited as long as the uneven portion of the substrate includes at least one selected from among a mask and an opening. The uneven portion of the substrate may be two or more masks. Also, the uneven portion of the substrate may be two or more openings. Furthermore, the uneven portion of the substrate may be a combination of a mask and an opening. The uneven portion of the substrate may include regularly arranged masks and/or openings. Also, the uneven portion of the substrate may include irregularly arranged masks and/or openings. In embodiments of a present inventive subject matter, the masks and/or the openings of the uneven portion are arranged at a regular interval. The regular interval may be set as a distance between a center of a first mask and a center of a second mask that is positioned adjacent to the first mask or a distance between a center of a first opening and a center of a second opening that is positioned adjacent to the first opening, for example. In embodiments of a present inventive subject matter, the masks and/or the openings of the uneven portion are preferably arranged regularly and repeatedly as a regular pattern. Examples of the regular pattern of mask include a striped pattern, a dot pattern, and a lattice pattern. In embodiments of a present inventive subject matter, the masks and/or the openings of the uneven portion are preferably arranged in a striped pattern or in a dot pattern, and further preferably arranged in a dot pattern. The masks and/or the openings each in the shape of polygon in a plan view may be arranged. Examples of the polygon include a triangle, a quadrangle, a pentagon, and a hexagon in a plan view. Also, examples of the quadrangle include a square, a rectangle and a trapezoid. Furthermore, the masks and/or the openings may be regularly and repeatedly arranged as a pattern. Examples of the mask of the uneven portion appear to be circles arranged in a grid pattern at a regular interval in a top plan view as shown in FIG. 3, regular squares, triangles at a regular interval in a top plan view as shown in FIG. 5.

Material component of the at least one mask is not particularly limited and may be a known material component. The mask of the uneven portion may be electrically-insulating. Also, the mask of the uneven portion may be electrically conductive. The mask of the uneven portion may be semi-conductive. The material component of the mask of the uneven portion may be amorphous. The material component of the mask of the uneven portion may be monocrystalline. Also, the material component of the mask of the uneven portion may be polycrystalline. Examples of the material component of the mask of the uneven portion include an oxide, a nitride, a carbide, carbon, diamond, a metal, and a mixture of at least two selected from among an oxide, a nitride, a carbide, carbon, diamond, and a metal. Examples of the oxide include silicon (Si) oxide, germanium (Ge) oxide, titanium (Ti) oxide, zirconium (Zr) oxide, hafnium (Hf) oxide, tantalum (Ta) oxide, and tin (Sn) oxide. More specifically, the material component of the mask of the uneven portion may be silicon-containing compounds containing at least one selected from among SiO₂, SiN and polycrystalline silicon as a major component, and a metal having a melting point higher than a crystal growth temperature of a crystalline film that is a crystalline oxide semiconductor film. Examples of the metal having the melting point higher than the crystal growth temperature of the crystalline film include platinum, gold, silver, palladium, rhodium, iridium, and ruthenium. Also, the major component of the mask of the uneven portion accounts for 50% or more at a composition ratio, preferably 70% or more, and most preferably 90% or more.

The mask of the uneven portion may be formed by a known method. Examples of the known method include photolithography, electron beam lithography, laser patterning, and etching such as dry etching and wet etching. In embodiments of a present inventive subject matter, masks in the shape of ridges are preferably arranged in parallel, and masks in the shape of ridges are further preferably arranged in a grid pattern at a regular interval. In embodiments of a method for producing a crystalline film of a present inventive subject matter, the crystalline substrate is preferably a patterned sapphire substrate (PSS). Shapes of the masks of the uneven portion can be formed as a pattern. The shapes of the pattern include circular cones, hemispherical shapes, dome shapes, quadrangular prisms, and quadrangular pyramids. Also, the distance between each shape of the masks is not particularly limited, however, in embodiments of a present inventive subject matter, the distance is preferably 5 μm or less, and further preferably in a range or 1 μm to 3 μm.

The opening of the uneven portion is not particularly limited, and in the opening a surface of a substrate may be exposed. A surface in the opening of the uneven portion may contain the same or similar material components to the material components of the mask. Also, according to embodiments of a present inventive subject matter, the opening of the uneven portion is preferably an opening positioned on a surface of a substrate. Also, according to embodiments of a present inventive subject matter, the opening of the uneven portion is just a surface of a substrate. Furthermore, according to an embodiment of a present inventive subject matter, the opening of the uneven portion may be a pass-through hole formed in a mask. Also, according to an embodiment of a present inventive subject matter, the opening of the uneven portion may be a recessed portion formed in a surface of the substrate. The opening may be formed by a known method. Also, the same and similar techniques to the known method of the mask mentioned above including photolithography, electron beam lithography, laser irradiation, and etching such as dry etching and wet etching are applied to form the opening. The opening of the uneven portion may be a groove. The width and depth of the groove and the size of an upper surface of a flat portion exposed in the groove are not particularly limited, as long as an object of a present inventive subject matter is not interfered with. The flat portion surrounded by the groove may be a surface of the substrate or a mask. According to an embodiment of a present inventive subject matter, a crystalline film may include at least one mask with two or more openings. In the opening, air or an inert gas may be contained.

According to an embodiment of a method for producing a crystalline film of a present inventive subject matter, a substrate includes an uneven portion arranged on a surface of the substrate as shown in FIG. 2. The uneven portion on the surface of the substrate in this embodiment are masks 2a arranged on the surface of the substrate 1. FIG. 3 shows a schematic top plan view of the substrate with the uneven portion formed on the surface 1a of the substrate 1. As shown in FIG. 2 and FIG. 3, the masks 2a are arranged with a regular interval “a”. The regular interval “a” may be set as a distance between a center of a first mask and a center of a second mask that is positioned adjacent to the first mask. A plurality of masks 2a in this embodiment are spaced from one another and are separated from one another. The regular interval “a” is not particularly limited but in this embodiment, is preferably in a range of 0.5 μm to 10 μm. The regular interval “a” in this embodiment further preferably is in a range of 1 μm to 5 μm, and most preferably in a range of 1 μm to 3 μm. Examples of the shape of the mask 2a in this embodiment is a circular cone, and a hemispherical shape. The mask 2a may be formed by a photolithography, for example.

FIG. 4 shows a schematic perspective view of a substrate with an uneven portion formed on a surface of the substrate according to a present inventive subject matter as an example. FIG. 5 shows a top plan view of the substrate with the uneven portion formed on the surface of the substrate. The uneven portion of this embodiment has a shape different from the shape of the uneven portion shown in FIG. 2 and FIG. 3. The uneven portion shown in FIG. 4 are masks that are arranged on a surface of the substrate. The shape of the masks 2a in this embodiment is a triangular pyramid. The masks of triangular pyramids are arranged with a regular interval, which may be set as a regular distance “a” between a center of a first triangular pyramid and a center of a second triangular pyramid that is positioned adjacent to the first triangular pyramid. The triangular pyramids in this embodiment may be arranged in laterally and obliquely parallel as shown in FIG. 5. Also, two or more triangular pyramids may be in contact with adjacent triangular pyramids at apexes of the triangular pyramid. The regular interval “a” is not particularly limited but in this embodiment, preferably in a range of 0.5 μm to 10 μm. The regular interval in this embodiment further preferably in a range of 1 μm to 5 μm, and most preferably in a range of 1 μm to 3 μm. In this embodiment, the mask has a regular triangular shape in a plan view, and the opening has a regular triangular shape in a plan view.

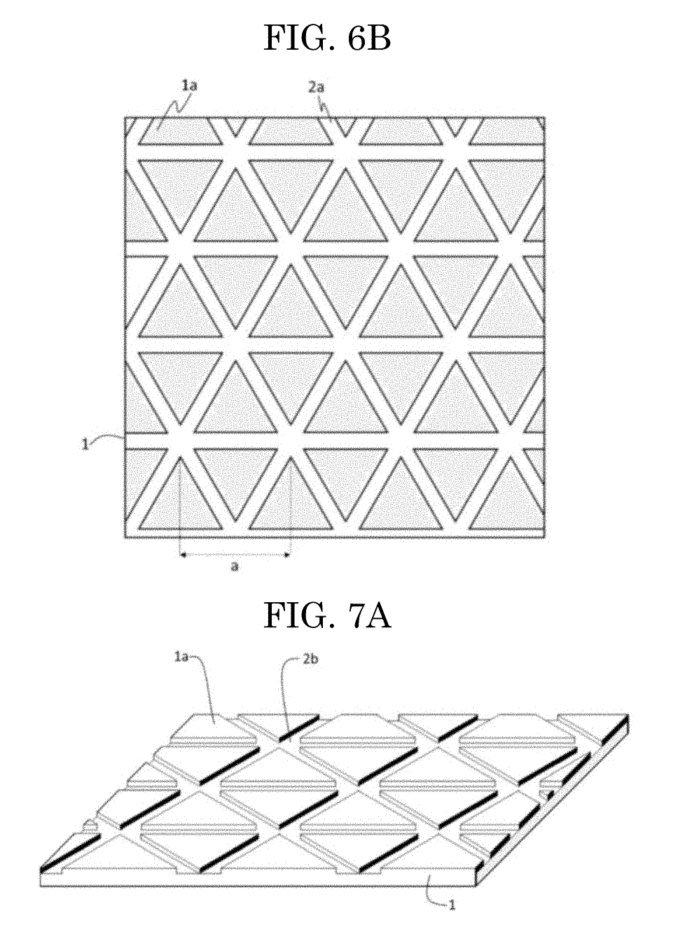

FIG. 6A shows a schematic perspective view of a substrate with an uneven portion formed on a surface of the substrate according to a present inventive subject matter. FIG. 6B shows a schematic top plan view of a substrate with an uneven portion formed on a surface of the substrate shown in FIG. 6A.

The uneven portion of this embodiment is a sheet-shaped mask 2a with two or more openings 2b arranged on the surface of the substrate 1. In the openings 2b of the mask 2a, the surface 1a of the substrate appears, as shown in FIG. 6A and FIG. 6B. In this embodiment, the mask 2a appears to be a lattice with triangular openings 2b. Examples of the shape of openings 2b include circle, triangle, a quadrangle, a pentagon and/or a hexagon in a plan view.

The mask 2a may be made of the same material of the substrate. Also, the mask may be made of a silicon-containing compound, which may be SiO₂. Furthermore, the mask 2a may be formed by a photolithography, for example. The regular interval “a” may be set as a distance between a center of a first opening and a center of a second opening that is positioned adjacent to the first opening. The regular interval “a” is not particularly limited but in this embodiment, preferably in a range of 0.5 μm to 10 μm. The regular interval in this embodiment is further preferably in a range of 1 μm to 5 μm, and most preferably in a range of 1 μm to 3 μm.

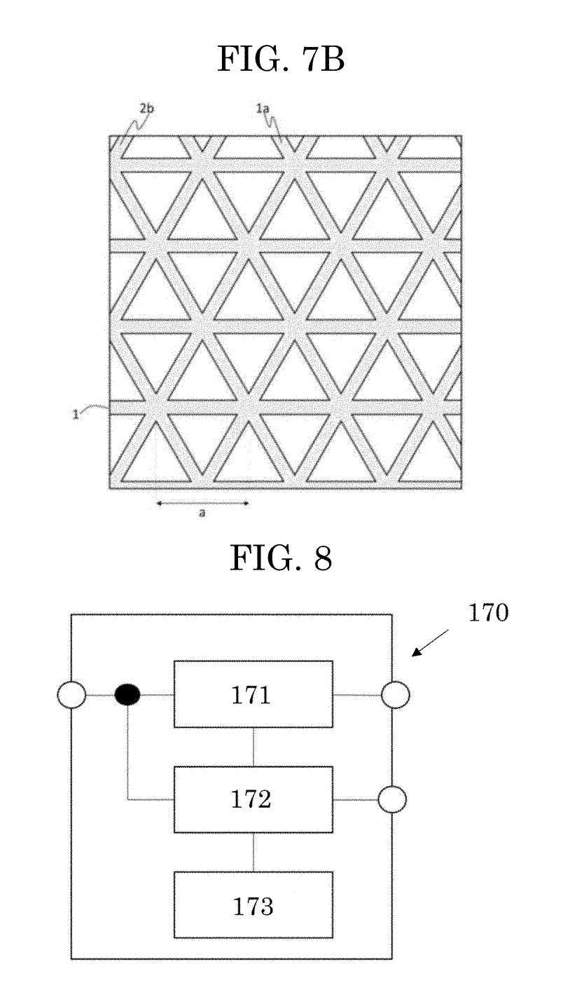

FIG. 7A shows a schematic perspective view of a substrate with an uneven portion formed on a surface of the substrate according to a present inventive subject matter as an example. In this embodiment, the opening 2b is a recessed portion formed in the substrate 1.

FIG. 7B shows a schematic top plan view of a substrate with an uneven portion formed on a surface of the substrate according to a present inventive subject matter as an example. The uneven portion of the substrate in this embodiment is an opening 2b surrounding triangular shapes of an upper surface of the substrate. The opening 2b may be formed by laser irradiation, for example. The triangular openings in this embodiment may be connected with adjacent triangular openings at apexes of the triangular openings, and the apexes may be set as the regular interval a. The regular interval a is not particularly limited but in this embodiment, preferably in a range of 0.5 μm to 10 μm. The regular interval in this embodiment is further preferably in a range of 1 μm to 5 μm.

The opening of the uneven portion may be a groove. The width and depth of the groove and the size of an upper surface of the substrate surrounded by the groove are not particularly limited, as long as an object of a present inventive subject matter is not interfered with. The flat portion surrounded by the groove may be a raised portion or a mask. According to an embodiment of a present inventive subject matter, a crystalline film may include an uneven portion including at least one mask and at least one opening. The at least one mask may include a plurality of masks. Also, the at least one opening may include a plurality of openings. The distance between adjacent masks and/or between adjacent openings is not particularly limited, however, according to an embodiment of a present inventive subject matter, the distance may be in a range of 10 nm to 1 mm, for example. In some embodiments of a present inventive subject matter, the distance between adjacent masks and/or between adjacent openings is preferably in a range of 10 nm to 300 μm, further preferably in a range of 10 nm to 1 μm, and most preferably in a range of 100 nm to 1 μm.

According to an embodiment of a present inventive subject matter, the substrate may include a buffer layer on top of the substrate. Also, if the substrate includes a buffer layer, the buffer layer on the substrate may include an uneven portion on a surface of the buffer layer. The uneven portion may include at least one mask and at least one opening. The buffer layer may include the uneven portion on an entire surface of the buffer layer. Examples of the method to form a buffer layer includes a spraying method, a mist Chemical Vapor Deposition (CVD) method, a Halide Vapor Phase Epitaxy (HVPE) method, a Molecular Beam Epitaxy (MBE) method, a Metalorganic Chemical Vapor Deposition (MOCVD) method, and a sputtering method. The buffer layer may be formed by a known method. In embodiments of a method for producing a crystalline film of a present inventive subject matter, the buffer layer is preferably formed by use of a mist CVD method, which is able to enhance quality of a crystalline film to be formed on the buffer layer with the uneven portion. The buffer layer formed by the mist CVD method on the substrate is useful to suppress occurrence of tilt that is included in a crystal defect. Embodiments of a method for producing a crystalline film on a buffer layer that is formed by use of a mist CVD method are explained in details as follows.

According to an embodiment to form a buffer layer by use of a mist CVD method, a buffer layer is preferably formed by turning a raw-material solution into atomized droplets, carrying the atomized droplets by use of a carrier gas onto a substrate, and adjusting the temperature of air and/or the substrate to cause thermal reaction of the atomized droplets adjacent to the substrate to form the buffer layer on the substrate.

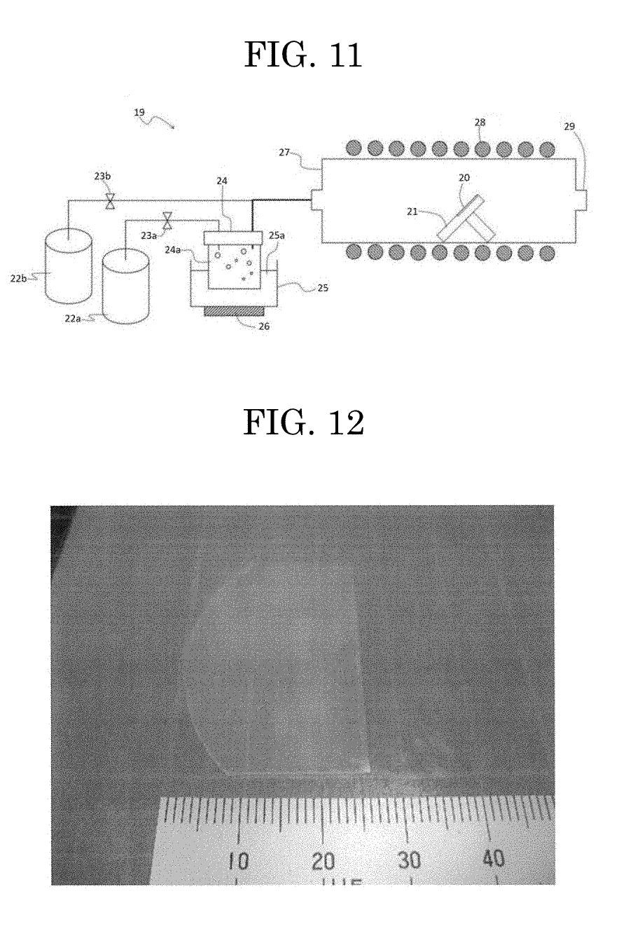

As an embodiment of a method of forming a crystalline layer, a mist chemical vapor deposition (CVD) method may be used. FIG. 11 shows a mist CVD apparatus 19 used in this embodiment. The mist CVD apparatus 19 includes a mist generator 24 with a container, and a vessel 25 containing water 25a, and an ultrasonic vibrator 26 attached to a bottom of the vessel 25. The mist CVD apparatus 19 further includes a carrier gas supply 22a, and a flow-control valve of carrier gas 23a. Furthermore, the mist CVD apparatus 19 may include a dilution carrier gas supply device 22b, and a flow-control valve of dilution carrier gas 23b. The mist CVD apparatus 19 includes a film-formation chamber 27 that may be a quartz tube with an inner diameter of 40 mm, a heater 28, and a stand 21 to support an object 20 in the film-formation chamber 27. The heater 28 may be arranged at a periphery of the film-formation chamber 27. A film is to be formed on the object, and the object may be a substrate. The stand 21 is made of quartz and includes a tilting surface, on which the object is placed. The tilting surface of the stand 21 may incline to a horizontal plane. The film-formation chamber 27 and the stage 21 both made of quarts tend to suppress entry of impurities originated from a material of parts and devices into a film to be formed on the object.

(Forming Atomized Droplets from a Raw Material Solution)

A raw material solution is turned into atomized droplets floating in a space of a container of a mist generator. The raw material solution may be turned into atomized droplets by a known method, and the method is not particularly limited, however, according to an embodiment of a present inventive subject matter, the raw material solution is preferably turned into atomized droplets by ultrasonic vibration. Atomized droplets including mist particles and obtained by using ultrasonic vibration and floating in the space have the initial velocity that is zero. Since atomized droplets floating in the space are carriable as a gas, the atomized droplets floating in the space are preferable to avoid damage caused by the collision energy without being blown like a spray. The size of droplets is not limited to a particular size, and may be a few mm, however, the size of atomized droplets is preferably 50 μm or less. The size of droplets is preferably in a range of 0.1 μm to 10 μm.

(Raw-Material Solution)

The raw-material solution is not particularly limited as long as a buffer layer is able to be formed from the raw-material solution by a mist CVD method. Examples of the raw-material solution include a solution of organometallic complex of a metal, and a solution of halide. Examples of the solution of organometallic complex include a solution of acetylacetonate complex. Examples of the solution of halide include a solution of fluoride, a solution of chloride, a solution of bromide and a solution of iodide. Examples of metal to be gasified include aluminum, indium, iron, chromium, vanadium, titanium, rhodium, nickel, cobalt, and iridium. One or more metals may be contained in the metal source. In an embodiment of a method for producing a crystalline film of a present inventive subject matter, the metal of the metal source may be at least one selected from among gallium, aluminum, and indium. Further preferably the metal of the metal source contains gallium, according to an embodiment of a present inventive subject matter. The amount of metal contained in the raw material solution is not particularly limited as long as an object of the present inventive subject matter is not interfered with, however, the amount of metal contained in the raw material solution is preferably 0.001 mol % to 50 mol %. The amount of metal contained in the raw material solution is further preferably 0.01 mol % to 50 mol %.

Also, according to an embodiment of a present inventive subject matter, a raw material solution may contain a dopant. By introducing a dopant into a raw material solution, it is possible to control electrical conductivity of a crystalline layer as a buffer layer, without ion implantation, for example, and thus, it is possible to form a semiconductor layer as a buffer layer without breaking a crystalline structure of the semiconductor layer as the buffer layer. Accordingly, this method is able to be used to control electrical conductivity of a buffer layer. Examples of n-type dopant include tin, germanium, silicon and lead. The n-type dopant is preferably tin or germanium, and most preferably tin. Examples of p-type dopant include magnesium, calcium, and zinc. The dopant concentration in general may be in a range of 1×10¹⁶/cm³ to 1×10²²/cm³. The dopant concentration may be at a lower concentration of, for example, approximately 1×10¹⁷/cm³ or less, also the dopant concentration may be at a high concentration of, for example, 1×10²⁰/cm³ or more. According to embodiments of a present inventive subject matter, the dopant concentration is preferably 1×10²⁰/cm³ or less, and further preferably 5×10¹⁹/cm³ or less.

According to an embodiment of a present inventive subject matter, a solvent of the raw material solution is not particularly limited and may be an inorganic solvent including water. Also, according to an embodiment, a solvent of the raw material solution may be an organic solvent including alcohol. Furthermore, according to an embodiment of a present inventive subject matter, a mixed solvent of water and alcohol may be used. According to embodiments of a present inventive subject matter, a solvent of the raw material solution preferably contains water, and a mixed solvent of water and alcohol is further preferably used, and most preferably, a solvent of the raw material solution is water, which may include, for example, pure water, ultrapure water, tap water, well water, mineral water, hot spring water, spring water, fresh water and ocean water. According to embodiments of a present inventive subject matter, ultrapure water is preferable as a solvent of a raw material solution.

(Carrying Atomized Droplets into a Film-Formation Chamber)

Atomized droplets floating in the space of a container for forming atomized droplets are carried into a film-formation chamber by a carrier gas. The carrier gas is not limited as long as an object of the present inventive subject matter is not interfered with, and thus, examples of the carrier gas may be an inert gas such as nitrogen and argon, may be an oxidizing gas such as oxygen and ozone, and may be a reducing gas such as a hydrogen gas and a forming gas. One or more carrier gas of the examples may be used, and a dilution gas at a reduced flow rate (e.g., 10-fold dilution gas) may be used as a second carrier gas. Also, the carrier gas may be supplied from one or more locations. While the flow rate of the carrier gas is not particularly limited, the flow rate of the carrier gas may be in a range of 0.01 to 20 L/min. According to an embodiment of a present inventive subject matter, the flow rate of the carrier gas may be preferably in a range of 1 to 10 L/min. When a dilution gas is used, the flow rate of the dilution gas is preferably in a range of 0.001 to 2 L/min, and further preferably in a range of 0.1 to 1 L/min.

### (Forming a Buffer Layer)

For forming a buffer layer, the atomized droplets carried into the film-formation chamber by carrier gas are thermally reacted (through “thermal reaction”) to form a buffer layer on a surface of a substrate. Herein, “thermal reaction” covers as long as the atomized droplets react by heat, and thus, the term “thermal reaction” herein may include a chemical reaction, and/or a physical reaction. The “thermal reaction” herein may include another reaction, and conditions of reaction are not particularly limited as long as an object of a present inventive subject matter is not interfered with. According to embodiments of a present inventive subject matter, the thermal reaction is conducted at an evaporation temperature or higher temperatures of the evaporation temperature of the solvent of the raw material solution, however, the temperature range for the “thermal reaction” is not too high and may be below 1000° C., for example. The thermal reaction is preferably conducted at a temperature below 650° C., and most preferably conducted at a temperature in a range of 400° C. to 650° C. Also, the thermal reaction may be conducted in any atmosphere of a vacuum, a non-oxygen atmosphere, a reducing-gas atmosphere, and an oxidizing-gas atmosphere. Also, the thermal reaction may be conducted in any condition of under an atmospheric pressure, under an increased pressure, and under a reduced pressure, however, according to embodiments of a present inventive subject matter, the thermal reaction is preferably conducted under an atmospheric pressure. Also, the thickness of the buffer layer is able to be set by adjusting a film-formation time.

As mentioned above, a buffer layer may be formed on at least a part of a surface of the substrate. It is also possible to form a buffer layer on an entire surface of the substrate. A crystalline film formed on the buffer layer that is formed on the substrate is able to decrease crystal defects such as tilts. Accordingly, it is possible to obtain a crystalline film in good quality with less defects.

The buffer layer is not particularly limited, however, in embodiments of a present inventive subject matter, the buffer layer preferably contains a metal oxide as a major component. Examples of the metal oxide include aluminum (Al) oxide, gallium (Ga) oxide, indium (In) oxide, iron (Fe) oxide, chromium (Cr) oxide, vanadium (V) oxide, titanium (Ti) oxide, rhodium (Rh) oxide, nickel (Ni) oxide, cobalt (Co) oxide, and iridium (Ir) oxide, and at least one of the examples of the metal oxide may be contained in the buffer layer as a major component. Of course, an oxide of a combination of two or more metals selected from among Al, Ga, In, Fe, Cr, V, Ti, Rh, Ni, Co, and Ir may be contained in the buffer layer as a major component. In embodiments of a present inventive subject matter, a buffer layer preferably contains at least one selected from among In, Al, and Ga as a major component. In an embodiment of a present inventive subject matter, a buffer layer further preferably contains In and/or Ga, and most preferably contains Ga. As an embodiment of a method for producing a crystalline film of a present inventive subject matter, a buffer layer may contain a metal oxide as a major component, and the metal oxide contains gallium and aluminum that is less in quantity than gallium contained in the metal oxide of the crystalline film. Also, according to an embodiment of a method for producing a crystalline film of a present inventive subject matter, a buffer layer may include a superlattice structure. In embodiments of a present inventive subject matter, the term “major component” herein means that a metal oxide as a major component accounts for 50% or more of entire components contained in the buffer layer at atomic ratio. In an embodiment of a present inventive subject matter, a buffer layer further preferably contains a metal oxide as a major component that accounts for 70% or more, and more preferably 90% or more of entire components contained in the buffer layer. This means that the metal oxide may account for 100% of a buffer layer.

The crystalline structure of a crystalline film is not particularly limited but in embodiments of a present inventive subject matter, the crystalline film preferably has a corundum structure and/or a β-gallia structure. The crystalline film further preferably has a corundum structure. The major component of the crystalline film may be different from the major component of the buffer layer as long as an object of a present inventive subject matter is not interfered with, however, according to embodiments of the present inventive subject matter, the crystalline film preferably contains a metal oxide as a major component that is the same as the metal oxide as a major component of the buffer layer.

In an embodiment of a method for producing a crystalline film, the method includes supplying a metal-containing raw-material gas, an oxygen-containing raw-material gas, and a reactive gas onto a substrate. The substrate may include a buffer layer on top of the substrate. Also, if desired, the method may include supplying a dopant-containing raw-material gas in addition to supplying the metal-containing raw-material gas, the oxygen-containing raw-material gas, and the reactive gas. In this embodiment, a crystalline film containing a metal oxide as a major component is formed under a gas flow of the dopant-containing raw-material gas and the reactive gas. It is preferable that the crystalline film is formed on the substrate that is heated or on the buffer layer on the substrate that is heated. The film-formation temperature is not particularly limited as long as an object of a present inventive subject matter is not interfered with, however, in embodiments of the method of a present inventive subject matter, the film-forming temperature is preferably 900° C. or less. The film-forming temperature is further preferably 700° C. or less, and most preferably in a range of 400° C. to 700° C. Also, the film formation may be conducted in any atmosphere of a vacuum, a non-vacuum environment, a reducing-gas atmosphere, an inert gas atmosphere and an oxidizing-gas atmosphere. Also, the film formation may be conducted in any condition of under an atmospheric pressure, under an increased pressure, and under a reduced pressure. According to embodiments of a present inventive subject matter, the film formation is preferably conducted under an atmospheric pressure. Also, a film thickness of crystalline oxide semiconductor film is able to be set by adjusting a film-formation time.

According to embodiments of a crystalline film of a present inventive subject matter, the crystalline film contains a crystalline metal oxide as a major component. Examples of the crystalline metal oxide include Al oxide, Ga oxide, In oxide, Fe oxide, Cr oxide, V oxide, Ti oxide, Rh oxide, Ni oxide, Co oxide, and Ir oxide. Of course, an oxide of a combination of two or more metals selected from among Al, Ga, In, Fe, Cr, V, Ti, Rh, Ni, Co, and Ir may be contained in the crystalline film as a major component. In embodiments of a present inventive subject matter, a crystalline film preferably contains at least one selected from among In, Al, and Ga as a major component. In an embodiment of a present inventive subject matter, a crystalline film further preferably contains In and/or Ga. The crystalline film most preferably contains a crystalline gallium oxide as a major component or a mixed crystal of gallium oxide as a major component, according to embodiments of a crystalline film of a present inventive subject matter. In embodiments of a crystalline film of a present inventive subject matter, the term “major component” herein means that a crystalline metal oxide as a major component accounts for 50% or more of entire components contained in the crystalline film at atomic ratio. In an embodiment of a present inventive subject matter, a crystalline film further preferably contains a metal oxide as a major component that accounts for 70% or more, and more preferably 90% or more of entire components contained in the crystalline film at atomic ratio. This means that the metal oxide may account for 100% of a crystalline film. The crystalline structure of a crystalline film is not particularly limited but in embodiments of a present inventive subject matter, the crystalline film preferably has a corundum structure and/or a β-gallia structure. The crystalline film further preferably has a corundum structure. The crystalline film is most preferably a crystal growth film including a corundum structure. The crystalline metal oxide contained in the crystalline film may be monocrystalline. Also, the crystalline metal oxide contained in the crystalline film may be polycrystalline. In an embodiment of a crystalline film of a present inventive subject matter, the crystalline metal oxide is preferably monocrystalline. The film thickness of the crystalline film is not particularly limited but the film thickness of the crystalline film is preferably 3 μm or more. Further preferably, the crystalline film is 10 μm or more in thickness, and most preferably 20 μm or more.

According to the method mentioned above, it is possible to obtain a crystal containing a corundum-structured semiconductor as a major component, and having a carrier concentration that is 1×10¹⁸/cm³ or more and an electron mobility that is 20 cm²/Vs or more, even though the crystal includes a principal plane that is a c-plane. The crystal according to this embodiment has a shape of film as a crystalline film. The corundum-structured semiconductor of the crystal contains gallium and/or indium and is doped with a dopant including germanium. The term “carrier concentration” herein means a carrier concentration in the crystalline film obtained by hall effect measurement of the crystalline film. Also, the term “electron mobility” herein means an electron mobility obtained by hall effect measurement of the crystalline film. According to an embodiment of a crystalline film of a present inventive subject matter, the principal plane preferably includes an off-angle. Also, according to an embodiment of a crystalline film of a present inventive subject matter, the corundum-structured oxide semiconductor preferably contains gallium. Furthermore, according to an embodiment of a crystalline film of a present inventive subject matter, the corundum-structured oxide semiconductor preferably contains a mixed crystal of gallium and one or more metals selected from among aluminum, indium, iron, chromium, vanadium, titanium, rhodium, nickel, cobalt, and iridium. A crystalline film of a present inventive subject matter includes a crystalline substrate, which is obtainable by setting a film-formation time to longer and/or increasing a film-formation speed, for example.

Also, according to the method mentioned above, it is possible to obtain a crystal containing an oxide semiconductor as a major component, and having a carrier concentration that is 1×10¹⁸/cm³ or more and an electron mobility that is 20 cm²/Vs or more, even though the crystal contains aluminum that is 1×10¹⁷/cm³ or more. The crystal according to this embodiment has a shape of film as a crystalline film that is expected to be thermally more stable, compared to an α-phase gallium oxide film, for example. Furthermore, the crystalline film of this embodiment is able to be used in a semiconductor device that tends to be exposed to a high temperature. According to this embodiment, the crystalline film preferably contains a mixed crystal containing gallium and one or more metals selected from among aluminum, indium, iron, chromium, vanadium, titanium, rhodium, nickel, cobalt, and iridium. A crystalline film of a present inventive subject matter includes a crystalline substrate. It is possible to change the thickness of the crystalline film by setting a film-formation time to longer and/or increasing a film-formation speed, for example.

A crystalline film obtained by a method for producing a crystalline film of an embodiment of a present inventive subject matter, is used for a semiconductor device including a power device. A power device using a crystalline film of a present inventive subject matter, for example, is expected to be a switching device achieving a high withstand voltage. Also, such a device is expected to obtain a high thermal resistance. Examples of the semiconductor device include a transistor such as a high-electron-mobility transistor (HEMT), a metal insulator semiconductor (MIS), a thin-film transistor (TFT), a semiconductor device, a Schottky barrier diode (SBD), a p-n junction diode, a PIN diode, a light-emitting element and a photodetector device. According to an embodiment of a present inventive subject matter, a crystalline film separated from a substrate may be used in a semiconductor device. Also, according to an embodiment of a present inventive subject matter, a crystalline film formed on the substrate may be used in a semiconductor device.

In addition, according to an embodiment of a semiconductor device of a present inventive subject matter, the semiconductor device may be used as a power module, an inverter, and/or a converter. Also, a semiconductor device according to a present inventive subject matter may be used in a semiconductor system including a power source, to which the semiconductor device may be electrically connected by a known structure and/or method. The semiconductor device may be electrically connected to a wiring pattern in the semiconductor system.

FIG. 8 shows schematic view of a semiconductor system according to an embodiment of a present inventive subject matter. The semiconductor system may be a power system 170. The power system 170 may include two or more power devices and a control circuit. The power system 170 shown in FIG. 8 may include a first power system 171 and a second power system 172 and a control circuit 173 that are electrically connected in the power system 170.

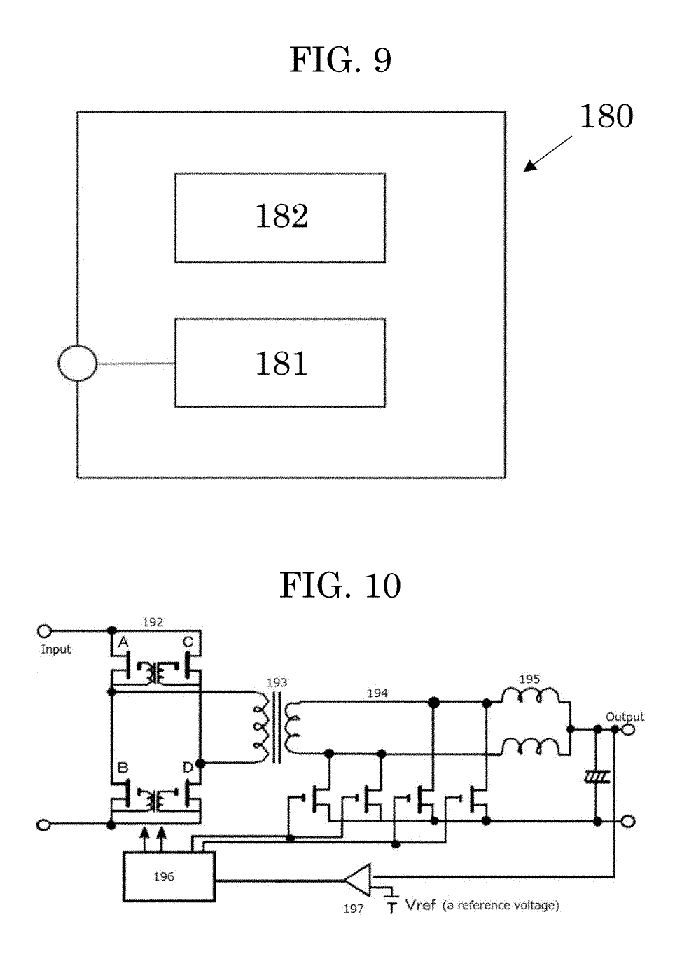

FIG. 9 shows a schematic view of a semiconductor system according to an embodiment of a present inventive subject matter. The semiconductor system may be a system device 180, as shown in FIG. 9. The system device 180 may include a power system 181 and an electric circuit 182 that may be combined with the power system 181.

FIG. 10 illustrates a power supply circuit 191 of a power supply device, including a power circuit and a control circuit. A DC voltage is switched at high frequencies by an inverter 192 (configured with MOSFET A to D) to be converted to AC, followed by insulation and transformation by a transformer 193. The voltage is then rectified by rectification MOSFETs 194 and then smoothed by a DCL 195 (smoothing coils L1 and L2) and a capacitor to output a direct current voltage. At this point, the output voltage is compared with a reference voltage by a voltage comparator 197 to control the inverter and the rectification MOSFETs by a PWM control circuit 196 to have a desired output voltage.

Embodiments are explained in more details.

### Example 1

1. HVPE Apparatus

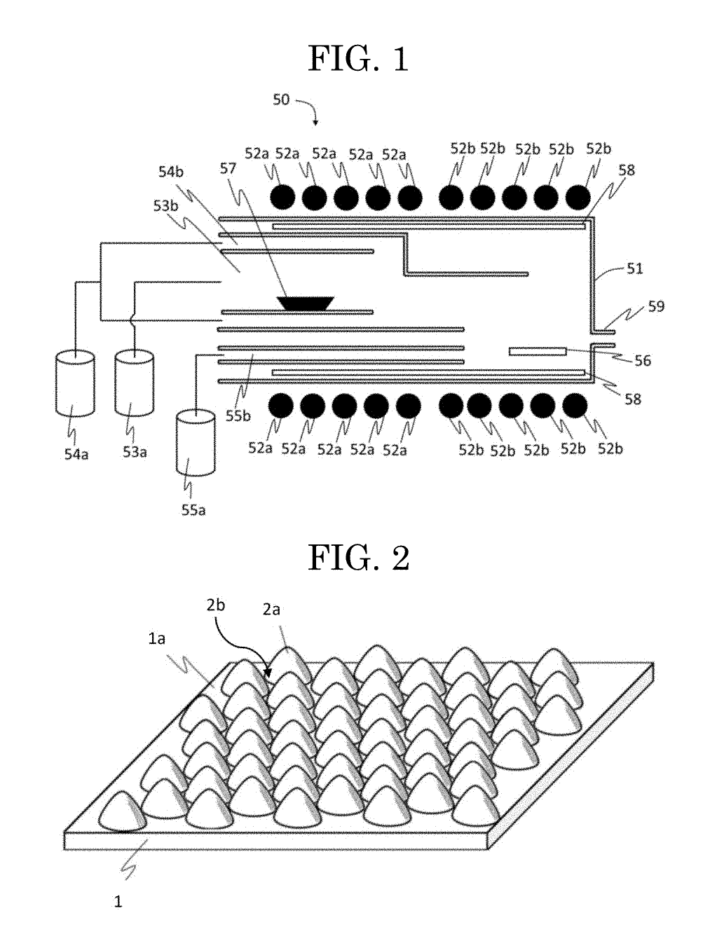

With reference to FIG. 1, an HVPE apparatus that was used in this embodiment of a method for producing a crystalline film is described. The HVPE apparatus 50 includes a reaction chamber 51, a heater 52a to heat a metal source 57, and a heater 52b to heat an object that may be a substrate held by the substrate holder 56. The HYPE apparatus 50 further includes a supply tube 55b of oxygen-containing raw material gas, a supply gas tube 54b of reactive gas, and a substrate holder 56, on which the substrate is placed, in the reaction chamber 51. Furthermore, a supply tube 53b of metal-containing raw-material gas was arranged in the supply gas tube 54b of reactive gas to have a double-tube structure. The supply tube 55b of oxygen-containing raw material gas is connected to the supply device 55a of oxygen-containing raw material gas to form a flow path of the oxygen-containing raw material gas such that the oxygen-containing raw-material gas is supplied to the substrate held by the substrate holder 56. The supply tube 53b of metal-containing raw-material gas is connected to the supply device 53a of halogen-containing raw-material gas such that the halogen-containing raw-material gas is supplied to the metal source to form metal-containing raw-material gas. The metal-containing gas is then supplied onto the substrate held by the substrate holder 56. The reaction chamber 51 further includes a gas discharge portion 59 to discharge used gas and a protection sheet 58 arranged on an inner surface of the reaction chamber 51 to prevent reacted material from depositing on.

2. Film (Layer) Formation Preparation

A gallium (Ga) metal source 57 (99.99999% or higher purity) was arranged in the supply tube 53b of metal-containing raw-material gas, and a c-plane sapphire substrate was placed on the substrate holder 56 as a substrate in the reaction chamber 51. After that the heater 52a and the heater 52b were activated to raise the temperature of the reaction chamber 51 up to 550° C.

3. Formation of a Film

Hydrogen chloride (HCl) gas (99.999% or higher purity) was supplied from the supply device 53a of halogen-containing raw-material gas to the Ga metal source 57 arranged in the supply tube 53b of metal-containing raw-material gas to form a gallium chloride (GaCl/GaCl₃) by a chemical reaction of Ga metal and HCl gas. The obtained gallium chloride (GaCl/GaCl₃) that is supplied through the supply tube 53b of metal-containing raw-material gas and O₂ gas (99.99995% or higher purity) that is supplied through the supply tube 55b of the supply device 55a of oxygen-containing raw material gas s are supplied onto the substrate. Under a gas flow of HCl (99.999% or higher purity), the gallium chloride (GaCl/GaCl₃) and O₂ gas were reacted at 550° C. under atmospheric pressure to form a crystalline film on the substrate. The film-formation time was seven minutes. Here, a gas flow rate of HCl gas supplied from the supply device 53a of halogen-containing raw-material gas was maintained to be 5.0 sccm, a gas flow rate of the supply device 54a of reactive gas was maintained to be 5.0 sccm, a gas flow rate of germanium tetrachloride gas was maintained to be 10 sccm and a gas flow rate of the supply device 55a of oxygen-containing raw material gas was maintained to be 20 sccm, respectively.

4. Evaluation

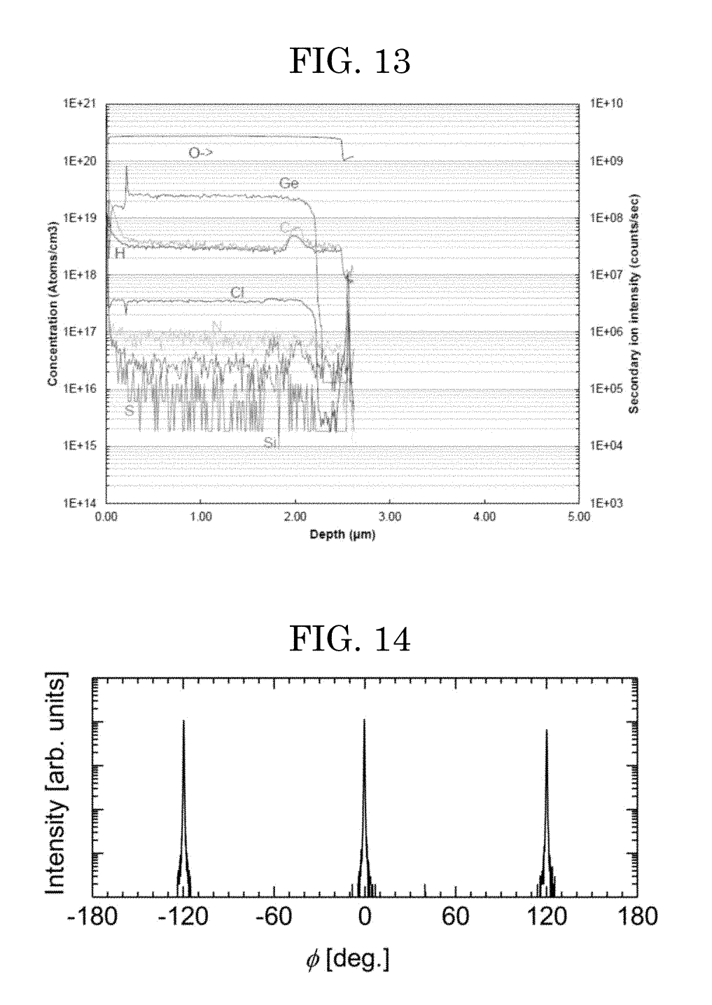

The film obtained at 3. was a crystalline film without a crack and abnormal growth, and identified by use of the X-ray diffraction (XRD) analysis of XRD 2θ/ω scans at an angle from 15 degrees to 95 degrees. The measurement was conducted by use of CuKα radiation. The film obtained was found to be a crystalline film of α-Ga₂O₃. Also, the crystalline film was analyzed by secondary-ion mass spectrometry (SIMS), and the analysis was performed with a Cameca SIMS instrument, primary ions are cesium (Cs) ions, and a first accelerating voltage was 14.5 kV. FIG. 13 shows the result, showing that germanium is doped in the crystalline film uniformly from a surface of the crystalline film to the depth of 2.0 μm. Furthermore, the Hall effect of the crystalline film was measured by the van der Pauw method. As a result, the crystalline film had a carrier concentration that is 9.1×10¹⁸/cm³ and an electron mobility that is 20 cm²/Vs. Also, FIG. 14 shows the result of XRD φ scan. As shown in FIG. 14, the film obtained at 3. was a crystalline film in good quality free from crystal twinning.

### Example 2

A crystalline film was obtained by the same conditions as the conditions of the Example 1 except the following one condition: supplying a germanium tetrachloride gas at a flow rate of 1 sccm instead of supplying the germanium tetrachloride gas at the flow rate of 10 sccm. The crystalline film that was obtained in this Example 2 was an α-Ga₂O₃ semiconductor film.

### Example 3

A crystalline film was obtained by the same conditions as the conditions of the Example 1 except the following one condition: supplying a germanium tetrachloride gas at a flow rate of 3 sccm instead of supplying the germanium tetrachloride gas at the flow rate of 10 sccm. The crystalline film that was obtained in this Example 3 was an α-Ga₂O₃ semiconductor film.

### Example 4

A crystalline film was obtained by the same conditions as the conditions of the Example 1 except the following one condition: supplying a germanium tetrachloride gas at a flow rate of 3 sccm instead of supplying the germanium tetrachloride gas at the flow rate of 10 sccm. The crystalline film that was obtained in this Example 4 was an α-Ga₂O₃ semiconductor film.

Table 1 shows the measurement results of electron concentration and electron mobility of α-Ga₂O₃ semiconductor films obtained at Example 1 to Example 4, measured by Hall measurement at room temperature. Each of the α-Ga₂O₃ semiconductor films obtained at Example 1 to Example 4 indicates n-type conductivity. Table 1 shows that electron concentration is able to control by changing the flow rate (sccm) of germanium tetrachloride gas.

TABLE 1

| Flow rate (sccm) | Electron | |
|---|---|---|
| of germanium | concentration (cm⁻³) at | Electron mobility (cm²/Vs) at |
| tetrachloride gas | room temperature | room temperature |
| 1 | 2.93 × 10¹⁸ | 0.39 |
| 3 | 6.72 × 10¹⁸ | 38.13 |
| 6 | 2.61 × 10¹⁹ | 20.45 |
| 10 | 9.1 × 10¹⁸ | 19.93 |

### Comparative Example 1

A crystalline film was obtained by the same conditions as the conditions of the Example 1 except the following one condition: without supplying the reactive gas (HCl gas) to the substrate. As a result, the film-formation rate became one tenth or less compared to the film-formation rate of Example 1. Also, the film obtained in Comparative Example 1 deteriorated in film quality of surface flatness, and the film did not have a mirror surface.

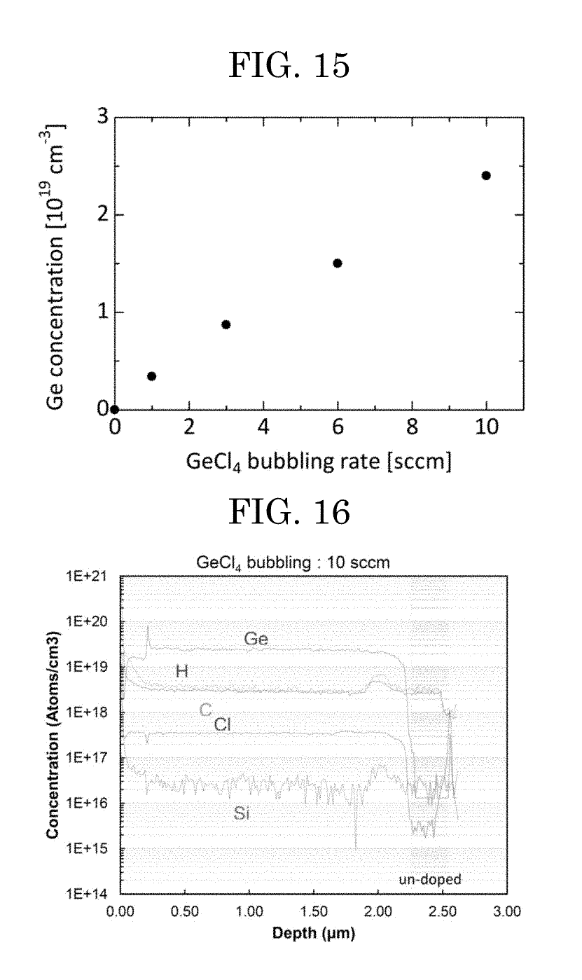

Each of the α-Ga₂O₃ semiconductor films obtained at Example 1 to Example 4 and the α-Ga₂O₃ film obtained at Comparative Example 1 were analyzed by SIMS. The relationship of Ge concentration in each of the obtained films and quantity of GeCl₄ supply were found to be proportional, as clearly shown in FIG. 15. Accordingly, it is found that doping concentration of a crystalline film is able to be controlled by the method used in embodiments of a present inventive subject matter.

### Test Embodiment 1

Also, a layered film including a first crystalline film of α-Ga₂O₃ grown without a dopant being doped and a second crystalline film of α-Ga₂O₃ grown with a dopant that is germanium being doped was formed. The second crystalline film of α-Ga₂O₃ doped with germanium was grown on the first crystalline film of α-Ga₂O₃. The layered film was examined and evaluated about being doped. Conditions of forming the layered film is shown in Table 2. Also, FIG. 19 is a schematic figure showing a film-formation device used in this Test Embodiment 1.

TABLE 2

| | |
|---|---|
| Pressure in the reaction chamber | Atmospheric pressure |
| Temperature of a raw-material portion | 560° C. |
| Temperature of a growth portion of crystal | 560° C. |
| Carrier gas | N₂ |
| Partial pressure of HCl supply | 2.5 × 10⁻¹ kPa |
| Partial pressure of O₂ supply | 1.0 kPa |
| Substrate | a c-plane sapphire substrate |

FIG. 19 schematically shows an HVPE apparatus used to grow the first crystalline film of α-Ga₂O₃ and the second crystalline film of α-Ga₂O₃ of the layered film in Test Embodiment 1. For more details, gallium chloride (GaCl) gas was used as a metal-containing raw-material gas. Also, germanium tetrachloride (GeCl₄) gas was used as the dopant-containing gas to form the second crystalline film of α-Ga₂O₃ of the layered film. The pressure in the reaction chamber was atmospheric pressure. The temperature of the raw-material portion was set to 560° C. Also, the temperature of the growth portion of crystal was set to 560° C. Nitrogen (N₂) was used as a carrier gas. Furthermore, HCl gas was supplied with the partial pressure of 2.5×10⁻¹ kPa. Oxygen (O₂) gas was supplied with the partial pressure of 1.0 kPa. The first crystalline film of α-Ga₂O₃ of the layered film was formed with the same conditions as the conditions to form the second crystalline film of α-Ga₂O₃ of the layered film except the following one condition: without using the dopant-containing gas. Accordingly, the layered film was obtained by forming the first crystalline film of α-Ga₂O₃ without a dopant being doped on the c-plane sapphire substrate, and forming the second crystalline film of α-Ga₂O₃ with germanium being doped on the first crystalline film of α-Ga₂O₃

The layered film obtained in the Test Embodiment 1 was analyzed by secondary-ion mass spectrometry (SIMS). As clearly shown in the analyzed result of SIMS of FIG. 16, doping delay and diffusion were not observed. Also, Ge concentration in the first crystalline film of α-Ga₂O₃ of the layered film, immediately after the second crystalline film was formed with germanium doped, was below the detection limit. Furthermore, the second crystalline film of the layered film appears to be evenly doped with germanium.

### Test Embodiment 2

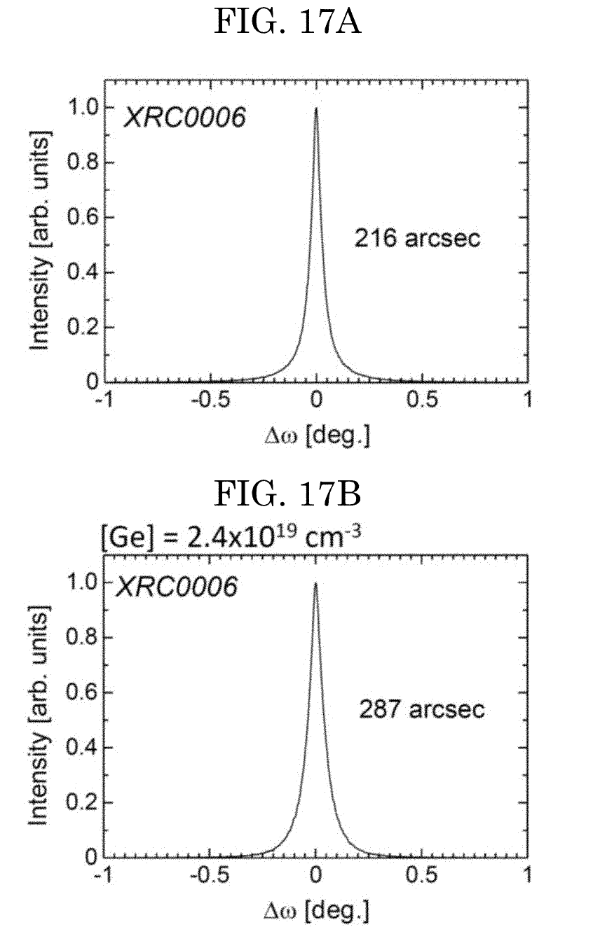

Also, similarly to the Test Embodiment 1, with the same conditions shown in Table 2, a layered film including a first crystalline film of α-Ga₂O₃ without a dopant being doped and a second crystalline film of α-Ga₂O₃ with germanium being highly doped (doping concentration: 2.4×10¹⁹/cm⁻³) was obtained. The XRD measurement result of the first crystalline film of α-Ga₂O₃ of the layered film in this Test Embodiment 2 is shown in FIG. 17A. Also, the XRD measurement result of the second crystalline film of α-Ga₂O₃ of the layered film in this Test Embodiment 2 is shown in FIG. 17B.

As shown in FIG. 17A and FIG. 17B, a difference in crystallinity of the second crystalline film that was highly doped with a dopant was not observed, compared with the first crystalline film without a dopant being doped.

Accordingly, it is clear that doping a dopant to a crystalline film according to an embodiment the method of a present inventive subject matter does not influence crystallinity of a crystalline film negatively.

### Test Embodiment 3

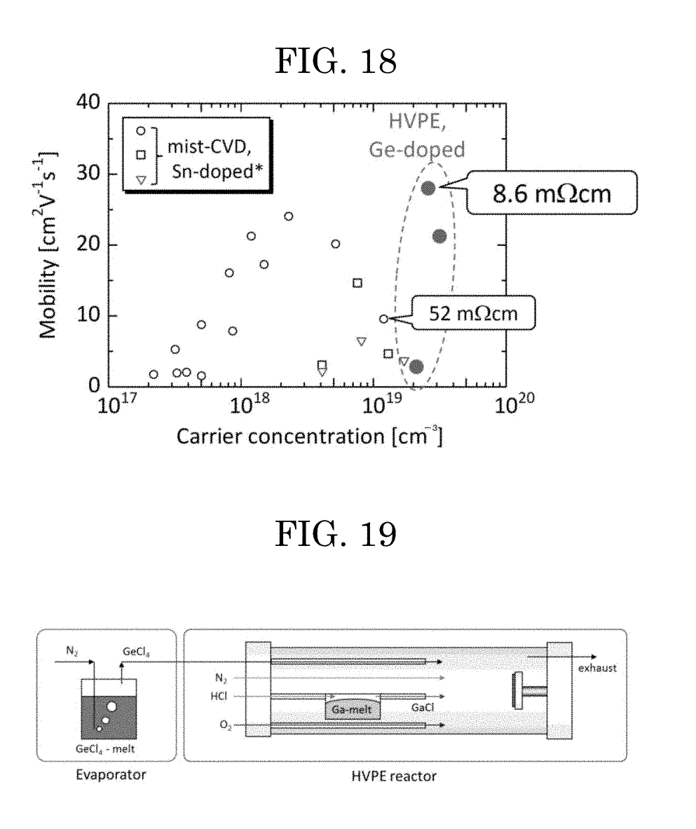

Also, a crystalline film of α-Ga₂O₃ with germanium being doped was similarly obtained according to the above-mentioned method. Furthermore, a crystalline film of α-Ga₂O₃ with tin (Sn) being doped was obtained by the mist CVD method. FIG. 18 shows the relationship of electron mobility and carrier concentration of the crystalline film of α-Ga₂O₃ with germanium being doped and the relationship of electron mobility and carrier concentration of the crystalline film of α-Ga₂O₃ with tin being doped.

The electron mobility of the crystalline film of α-Ga₂O₃ with germanium being doped was higher than the electron mobility of the crystalline film of α-Ga₂O₃ with tin being doped, and achieved an electrical resistivity that is 8.6 mΩ cm, which is considered to be a low electrical resistivity.

Accordingly, the crystalline film of α-Ga₂O₃ with a dopant being doped obtained by the method in embodiments of a present inventive subject matter was found to achieve good electrical properties.

### Example 5

A crystalline film was obtained by the same conditions as the conditions of the Example 1 except the following four conditions: using an m-plane sapphire substrate instead of using a c-plane sapphire substrate; setting the temperature in the reaction chamber to 540° C. instead of setting to 550° C. for forming the crystalline film; setting the film-formation time to seven minutes instead of setting to 15 minutes; and setting the flow rate of oxygen (O₂) gas to 100 sccm instead of setting to 20 sccm. The XRD measurement result of the crystalline film of α-Ga₂O₃ indicated that the crystallin film was superior in crystallinity. Also, it was found that the crystalline film grown on the m-plane was superior in electrical properties.

Furthermore, while certain embodiments of the present inventive subject matter have been illustrated with reference to specific combinations of elements, various other combinations may also be provided without departing from the teachings of the present inventive subject matter. Thus, the present inventive subject matter should not be construed as being limited to the particular exemplary embodiments described herein and illustrated in the Figures, but may also encompass combinations of elements of the various illustrated embodiments.

Many alterations and modifications may be made by those having ordinary skill in the art, given the benefit of the present disclosure, without departing from the spirit and scope of the inventive subject matter. Therefore, it must be understood that the illustrated embodiments have been set forth only for the purposes of example, and that it should not be taken as limiting the inventive subject matter as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive subject matter.

A method for producing a crystalline film according to an embodiment of a present inventive subject matter is able to be applied to methods for producing various devices including semiconductor devices, electronic devices, optical devices, power sources and power systems.

### REFERENCE NUMBER DESCRIPTION

a a regular interval
1 a substrate
1a a surface of the substrate 1
2a a mask
2b an opening
3 a crystalline film
4 a mask layer
5 a buffer layer
19 a mist CVD apparatus
20 an object on which a film is to be formed
21 a stand to support an object
22a a carrier gas supply device
22b a dilution carrier gas supply device
23a a flow-control valve of carrier gas
23b a flow-control valve of dilution carrier gas
24 a mist generator
24a a raw material solution
25 a vessel
25a water
26 an ultrasonic transducer
27 a film-formation chamber
28 a heater
50 a halide vapor phase epitaxy (HVPE) device
51 a reaction chamber
52a a heater
52b a heater
53a a supply device of halogen-containing raw-material gas
53b a supply tube of metal-containing raw-material gas
54a a supply device of reactive gas
54b a supply tube of reactive gas
55a a supply device of oxygen-containing raw material gas
55b a supply tube of oxygen-containing raw material gas
56 a substrate holder
57 a metal source
58 a protection sheet
59 a gas-discharge portion

What is claimed is:

1. A crystal comprising:
a corundum-structured oxide semiconductor as a major component, the corundum-structured oxide semiconductor comprising gallium and/or indium and doped with a dopant comprising germanium;
a principal plane;
a carrier concentration that is 1×10¹⁸/cm³ or more; and
an electron mobility that is 20 cm²/Vs or more.

2. The crystal of claim 1, wherein
the principal plane of the crystal is a c-plane.

3. The crystal of claim 1, wherein
the principal plane of the crystal is an m-plane.

4. The crystal of claim 1, wherein
the principal plane of the crystal comprises an off-angle.

5. The crystal of claim 1, wherein
the corundum-structured oxide semiconductor comprises a mixed crystal comprising gallium and one or more metals selected from among aluminum, indium, iron, chromium, vanadium, titanium, rhodium, nickel, cobalt, and iridium.

6. The crystal of claim 1, wherein
the crystal has a film shape as a crystalline film.

7. The crystal of claim 5, wherein the mixed crystal comprised in the corundum-structured oxide semiconductor comprises aluminum that is 1×10¹⁷/cm³ or more.

8. A crystalline film comprising:
an oxide semiconductor as a major component, the oxide semiconductor comprising aluminum that is 1×10¹⁷/cm³ or more;
a carrier concentration that is 1×10¹⁸/cm³ or more; and
an electron mobility that is 20 cm²/Vs or more.

9. The crystalline film of claim 8, wherein
the oxide semiconductor comprises gallium.

10. The crystalline film of claim 8, wherein
the oxide semiconductor comprises a mixed crystal.

11. A semiconductor device comprising:
the crystal of claim 6;
a first electrode electrically connected to the crystal; and
a second electrode electrically connected to the crystal.

12. A semiconductor device comprising:
a crystalline film of claim 8;
a first electrode electrically connected to the crystalline film; and
a second electrode electrically connected to the crystalline film.

13. A method for producing a crystalline film comprising:
gasifying a metal source to turn the metal source into a metal-containing raw-material gas;
supplying the metal-containing raw-material gas, an oxygen-containing raw-material gas into a reaction chamber onto a substrate;
supplying a dopant-containing raw-material gas and a reactive gas into the reaction chamber onto the substrate; and
forming a crystalline film under gas flow of the dopant-containing raw-material gas and the reactive gas.

14. The method of claim 13, wherein
the dopant-containing raw-material gas comprises germanium.

15. The method of claim 14, wherein
the dopant-containing raw-material gas is germanium halide gas.

16. The method of claim 13, wherein
the reactive gas is an etching gas.

17. The method of claim 13, wherein
the reactive gas comprises at least one selected from among hydrogen halide and groups comprising halogen and hydrogen.

18. The method of claim 13, wherein
The reactive gas comprises hydrogen halide.

19. The method of claim 13, wherein
the substrate comprises a corundum structure.

20. The method of claim 13, wherein
the crystalline film has a corundum structure.

21. The method of claim 13, wherein the substrate is heated with a temperature that is in a range of 400° C. to 700° C.

22. The method of claim 13, wherein
the metal source comprises gallium, and the metal-containing raw-material gas comprises gallium.

23. The method of claim 13, wherein
the gasifying the metal source is done by halogenating the metal source.

24. The method of claim 13, wherein
the oxygen-containing raw-material gas comprises at least one selected from among oxygen (O₂), water (H₂O) and nitrous oxide (N₂O).
